(19) United States
(12) Patent Application Publication
(10) Pub. No.: US 2025/0157913 A1
(43) Pub. Date: May 15, 2025

(54) SEMICONDUCTOR DEVICE

(71) Applicant: Rohm Co., Ltd., Kyoto-shi (JP)

(72) Inventors: Oji SATO, Kyoto-shi (JP); Kohei TANIKAWA, Kyoto-shi (JP)

(21) Appl. No.: 19/027,589

(22) Filed: Jan. 17, 2025

Related U.S. Application Data
(63) Continuation of application No. PCT/JP2023/023816, filed on Jun. 27, 2023.

(30) Foreign Application Priority Data
Jul. 27, 2022 (JP) 2022-119652

(51) Int. Cl. H01L 23/498; H01L 23/373; H01L 23/495; H01L 23/538; H01L 25/07

(52) U.S. Cl. CPC H01L 23/49866; H01L 23/3735; H01L 23/49575; H01L 23/538; H01L 25/072

(57) ABSTRACT

A semiconductor device includes a supporting layer, a conductive layer, a semiconductor element bonded to the conductive layer, a first coating layer, a second coating layer, and a bonding layer. The bonding layer includes a base layer, a third coating layer, and a fourth coating layer. A solid-state bonding layer is formed between the first coating layer and the third coating layer and between the second coating layer and the fourth coating layer. The base layer has a lower Vickers hardness than each of the supporting layer and the conductive layer. Each of the third coating layer and the fourth coating layer includes a first layer, a second layer, and a third layer. Diffusion from the second layer into each of the third layer, the first coating layer, and the second coating layer is more extensive than diffusion from the first layer into each of the third layer, the first coating layer, and the second coating layer.

### TECHNICAL FIELD

The present disclosure relates to semiconductor devices.

### BACKGROUND ART

JP-A-2017-174927 discloses an example of a semiconductor device that includes a circuit layer, and a semiconductor element electrically bonded to the circuit layer. The circuit layer includes a first layer and a second layer joined to the first layer by solid-state bonding. The first layer is joined to a ceramic substrate. This configuration ensures that the first layer, which may be an element of an insulating heat-dissipating substrate, and the second layer are reliably joined together, allowing the circuit layer to have a greater overall thickness. Such a circuit layer conducts heat more easily in a direction perpendicular to the stacking direction of the second layer relative to the first layer, improving the conductivity of heat from the circuit layer to the ceramic substrate. This consequently improves the heat dissipation of the semiconductor device.

To further improve the heat dissipation of the semiconductor device disclosed in JP-A-2017-174927, it is necessary to improve the efficiency of heat conduction between the first and second layers. This involves forming a stronger metallic bond at the interface between the first layer and the second layer joined by solid-state bonding.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1.

FIG. 3 is a plan view corresponding to FIG. 2, with a sealing resin shown as transparent.

FIG. 4 is a partially enlarged view of FIG. 3.

FIG. 5 is a plan view corresponding to FIG. 2, with a first conductive member shown as transparent and a sealing resin and a second conductive member omitted.

FIG. 6 is a right-side view of the semiconductor device shown in FIG. 1.

FIG. 7 is a bottom view of the semiconductor device shown in FIG. 1.

FIG. 8 is a sectional view taken along line VIII-VIII in FIG. 3.

FIG. 9 is a sectional view taken along line IX-IX in FIG. 3.

FIG. 10 is an enlarged view of FIG. 9, showing a portion around a first element.

FIG. 11 is an enlarged view of FIG. 9, showing a portion around a second element.

FIG. 12 is a sectional view taken along line XII-XII in FIG. 3.

FIG. 13 is a sectional view taken along line XIII-XIII in FIG. 3.

FIG. 14 is a partially enlarged view of FIG. 10.

FIG. 15 is a partially enlarged sectional view of a semiconductor device according to a second embodiment of the present disclosure.

FIG. 16 is a plan view of a semiconductor device according to a third embodiment of the present disclosure, with a first conductive member shown as transparent and a sealing resin and a second conductive member omitted.

FIG. 17 is a sectional view taken along line XVII-XVII in FIG. 16.

FIG. 18 is a sectional view taken along line XVIII-XVIII in FIG. 16.

FIG. 19 is a sectional view taken along line XIX-XIX in FIG. 16.

FIG. 20 is a plan view of a semiconductor device according to a fourth embodiment of the present disclosure, with a first conductive member shown as transparent and a sealing resin and a second conductive member omitted.

FIG. 21 is a sectional view taken along line XXI-XXI in FIG. 20.

FIG. 22 is a sectional view taken along line XXII-XXII in FIG. 20.

FIG. 23 is a sectional view taken along line XXIII-XXIII in FIG. 20.

### DETAILED DESCRIPTION OF EMBODIMENTS

Embodiments of the present disclosure are described below with reference to the accompanying drawings.

### First Embodiment

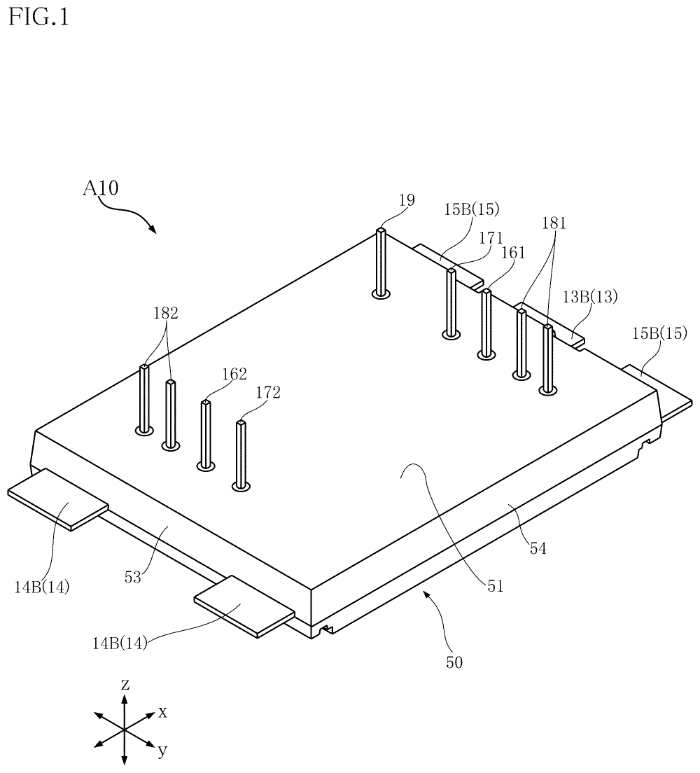

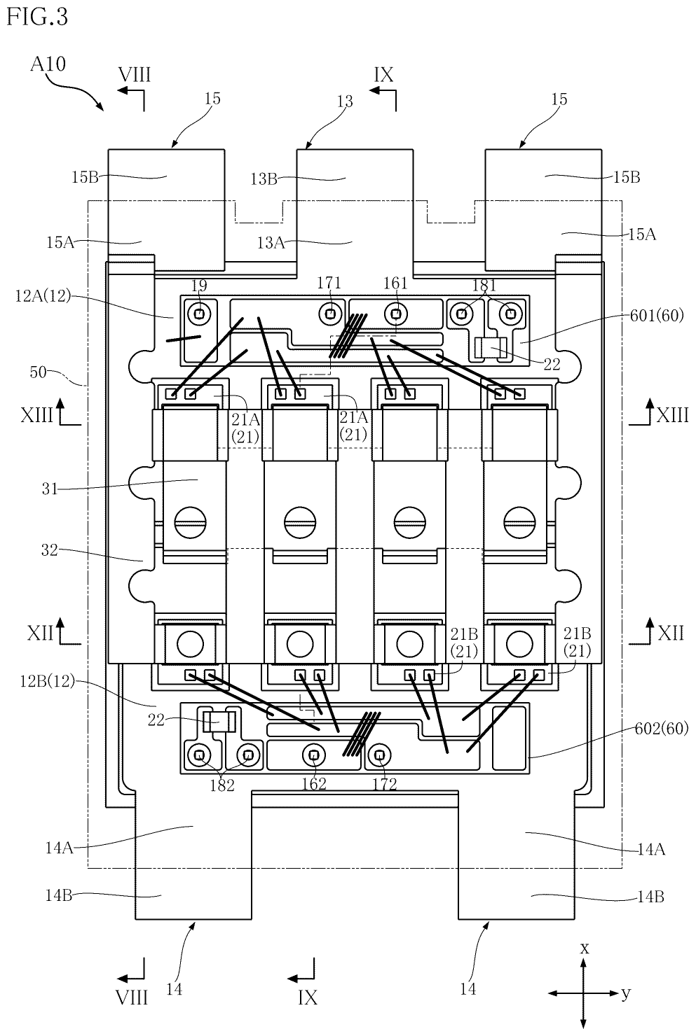

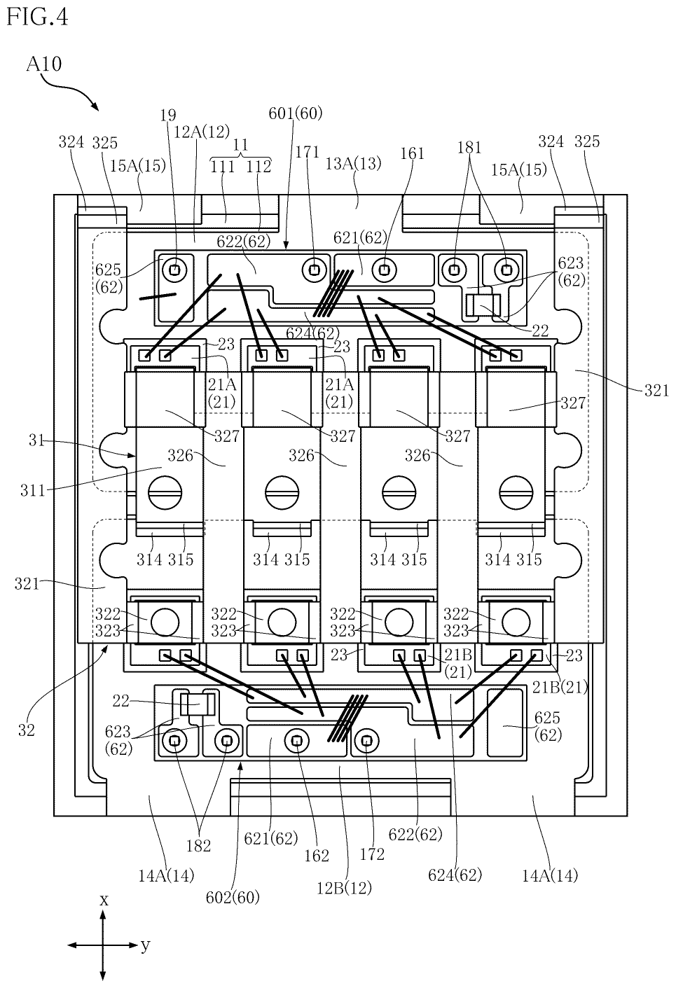

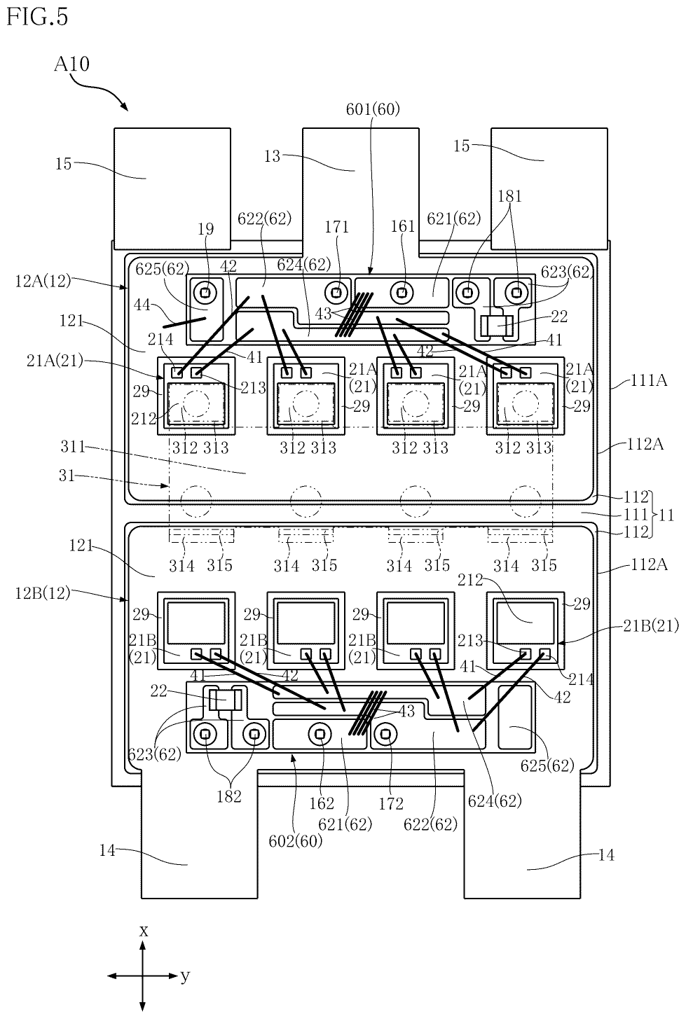

With reference to FIGS. 1 to 14, a semiconductor device A10 according to a first embodiment of the present disclosure is described. The semiconductor device A10 includes a substrate 11, two conductive layers 12, two first coating layers 71, two second coating layers 72, two bonding layers 73, a first input terminal 13, an output terminal 14, a second input terminal 15, a plurality of semiconductor elements 21, a first conductive member 31, a second conductive member 32, and a sealing resin 50. The semiconductor device A10 additionally includes a first signal terminal 161, a second signal terminal 162, a third signal terminal 171, a fourth signal terminal 172, two fifth signal terminals 181, two sixth signal terminals 182, a seventh signal terminal 19, two thermistors 22, and two control wirings 60. For the convenience of description, FIGS. 3 and 4 show the sealing resin 50 as transparent. FIG. 3 shows the outline of the sealing resin 50 with an imaginary line (dash-double dot line). For the convenience of description, FIG. 5 shows the first conductive member 31 as transparent and omits the second conductive member 32 and the sealing resin 50. FIG. 5 shows the outline of the first conductive member 31 with an imaginary line.

In the description of the present disclosure, the direction of the normal to the obverse surfaces 121 of the two conductive layers 12 described later is an example of a “first direction z. A direction perpendicular to the first direction z is an example of a “second direction x”. The direction perpendicular to the first direction z and the second direction x is an example of a “third direction y”. In the present disclosure, the term “as viewed in the first direction z” refers to the “plan view”.

The semiconductor device A10 converts the DC power supply voltage applied to the first input terminal 13 and the second input terminal 15 into AC power using the semiconductor elements 21. The resulting AC power is output from the output terminal 14 and supplied to a power supply target, such as a motor.

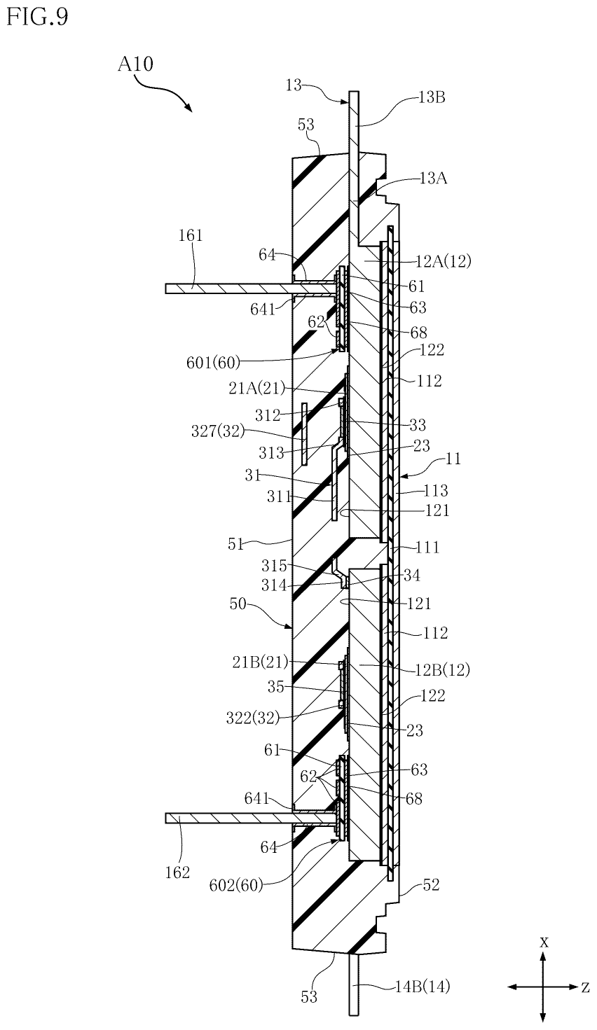

As shown in FIGS. 9 to 11, the substrate 11 is located opposite the semiconductor elements 21 in the first direction z with respect to the two conductive layers 12. The substrate 11 supports the two conductive layers 12. The substrate 11 is fabricated from a DBC (direct bonded copper) substrate, for example. As shown in FIGS. 9 to 11, the substrate 11 includes an insulating layer 111, two supporting layers 112, and a heat-dissipating layer 113. The substrate 11 is covered with the sealing resin 50, except for a portion of the heat-dissipating layer 113.

As shown in FIGS. 9 to 11, the insulating layer 111 is located opposite the two conductive layers 12 in the first direction z with respect to the two supporting layers 112. The insulating layer 111 is made of a material with relatively high thermal conductivity. The insulating layer 111 is made of a ceramic plate that contains aluminum nitride (AlN), for Instead of such a ceramic plate, the insulating example. layer 111 may be made from an insulating resin sheet containing filler with relatively high thermal conductivity. The insulating layer 111 has a smaller thickness than each conductive layer 12. In the present disclosure, a dimension in the first direction z is referred to as a “thickness”.

As shown in FIGS. 9 to 11, the two supporting layers 112 are located between the insulating layer 111 and the respective conductive layers 12. The supporting layers 112 are spaced apart from each other in the second direction x.

The supporting layers 112 are bonded to the insulating layer 111. The supporting layers 112 contain copper (Cu). As shown in FIG. 5, the supporting layers 112 are both enclosed in the peripheral edge 111A of the insulating layer 111 as viewed in the first direction z.

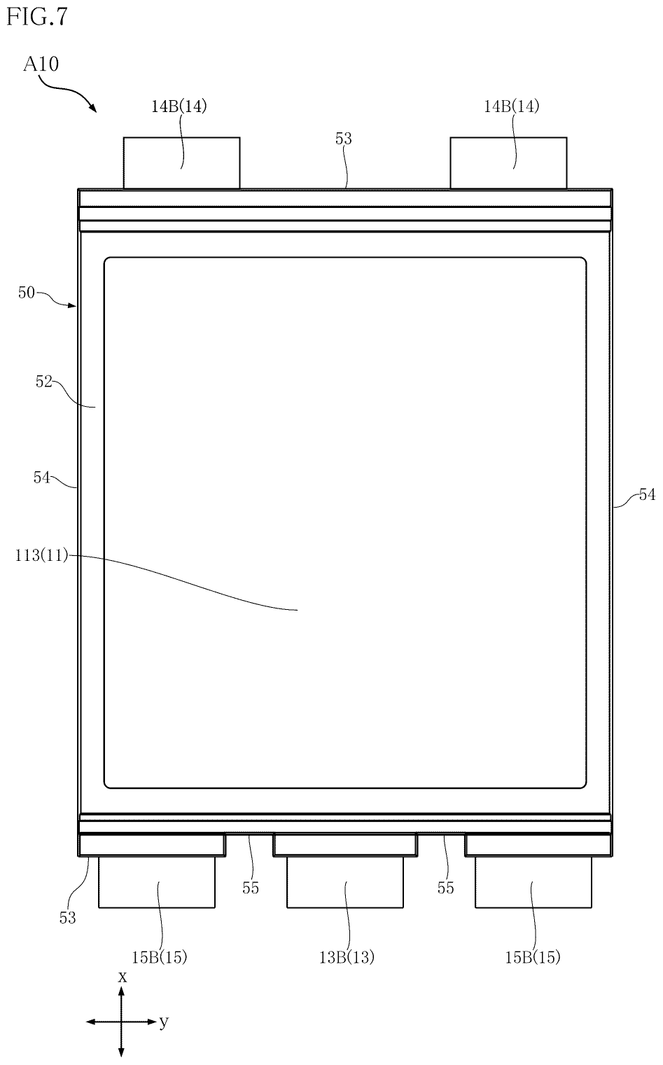

As shown in FIGS. 9 to 11, the heat-dissipating layer 113 is disposed opposite the two supporting layers 112 with respect to the insulating layer 111. The heat-dissipating layer 113 is bonded to the insulating layer 111. The heat-dissipating layer 113 contains copper. As shown in FIG. 7, the heat-dissipating layer 113 is exposed to the outside from the sealing resin 50. The heat-dissipating layer 113 has a greater thickness than the insulating layer 111. The thickness of the heat-dissipating layer 113 is equal to or greater than the thickness of each supporting layer 112. As viewed in the first direction z, the heat-dissipating layer 113 is enclosed in the peripheral edge 111A of the insulating layer 111 and overlaps with the entirety of each supporting layers 112.

As shown in FIGS. 9 to 11, the two conductive layers 12 are each bonded to the respective supporting layers 112. The two conductive layers 12 include a first conductive layer 12A and a second conductive layer 12B that are spaced apart from each other in the second direction x. The conductive layers 12 contain copper. The thickness of each conductive layer 12 is greater than the thickness of each supporting layer 112. As shown in FIG. 5, each conductive layer 12 is enclosed in the peripheral edge 112A of a corresponding supporting layer 112 as viewed in the first direction z.

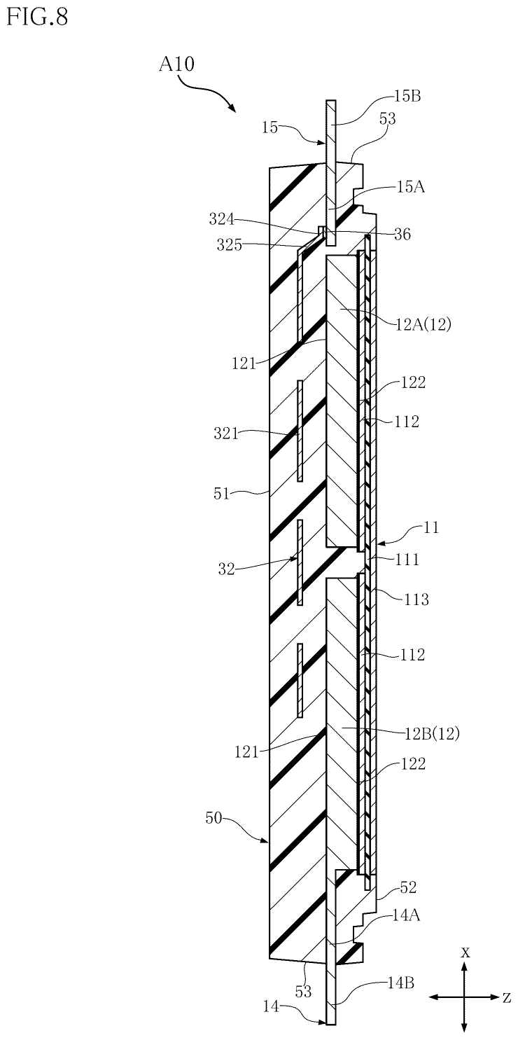

As shown in FIGS. 8 and 9, each conductive layer 12 has an obverse surface 121 and a reverse surface 122 facing away from each other in the first direction z. The obverse surface 121 faces some of the semiconductor elements 21. The reverse surface 122 faces a corresponding supporting layer 112. As viewed in the first direction z, the reverse surface 122 is enclosed in the peripheral edge 112A of the corresponding supporting layer 112. For each conductive layer 12, the area of the reverse surface 122 is equal to the area of the obverse surface 121.

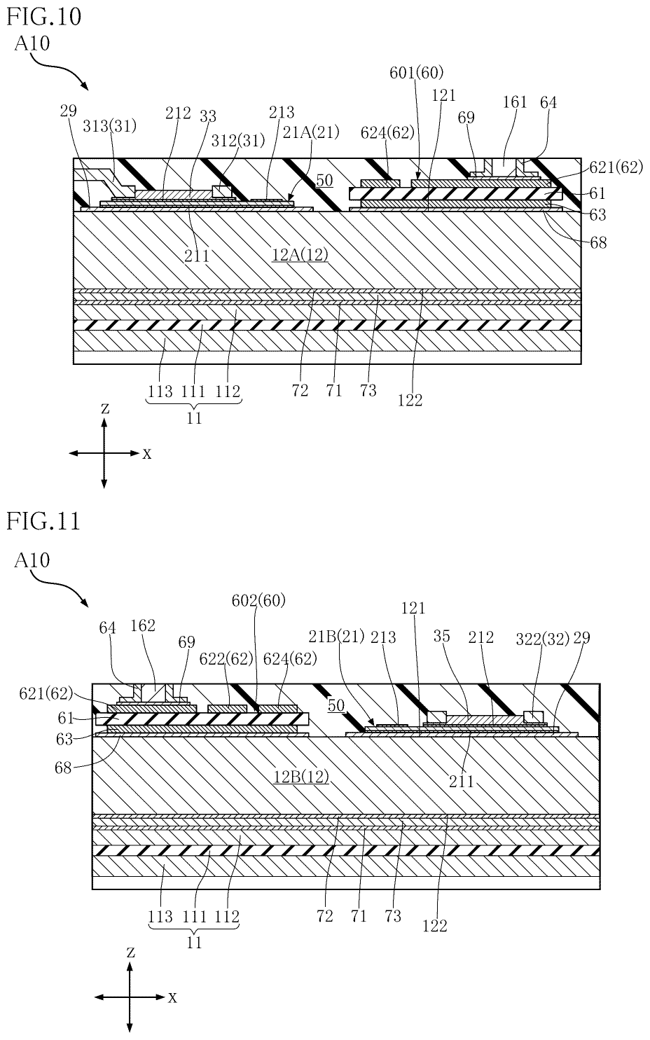

As shown in FIGS. 10 and 11, the two first coating layers 71 are located between the respective supporting layers 112 and the respective conductive layers 12, covering the supporting layers 112. The first coating layers 71 contain either silver (Ag) or gold (Au). When the first coating layers 71 contain silver, their thermal conductivity is higher than those of the supporting layers 112 and the conductive layers 12. The two first coating layers 71 may be thin films of metals that are deposited by sputtering on the respective supporting layers 112.

As shown in FIGS. 10 and 11, the two second coating layers 72 are located between the respective first coating layers 71 and the respective conductive layers 12, covering the reverse surfaces 122 of the conductive layers 12. The second coating layers 72 contain either silver or gold. When the second coating layers 72 contain silver, their thermal conductivity is higher than those of the supporting layers 112 and the conductive layers 12. The two second coating layers 72 may be thin films of metals deposited by sputtering on the respective supporting layers 112.

As shown in FIGS. 10 and 11, the two bonding layers 73 join the respective first coating layers 71 and the respective second coating layers 72. Thus, each bonding layer 73 is sandwiched between the corresponding first coating layer 71 and the corresponding second coating layer 72.

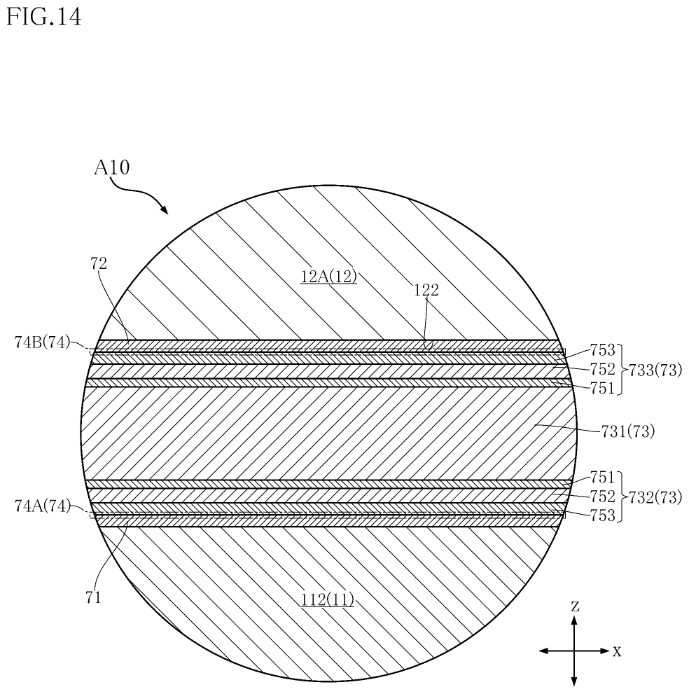

As shown in FIG. 14, each bonding layer 73 includes a base layer 731, a third coating layer 732, and a fourth coating layer 733. The base layer 731 is sandwiched between the third coating layer 732 and the fourth coating layer 733. The Vickers hardness of the base layer 731 is lower than those of the supporting layers 112 and the conductive layers 12. The base layer 731 contains aluminum (Al). The third coating a layer 732 is located between the base layer 731 and corresponding one of the two first coating layers 71. The fourth coating layer 733 is located between the base layer 731 and a corresponding one of the two second coating layers 72.

In the semiconductor device A10, the two second coating layers 72 are separately joined to the two first coating layers 71 each via the two bonding layers 73 by solid-state bonding. Solid-state bonding is conducted relatively at a high temperature and a high pressure. As a result, a solid-state bonding layer 74 is formed between one of the two bonding layers 73 and one of the two first coating layers 71 with an intervention of one of the two bonding layers 73 as shown in FIG. 14. The solid-state bonding layer 74 is a conceptual layer of metal bonds formed at the interface between two adjoining metal layers as a result that the two metal layers are joined by solid-state bonding. The solid-state bonding layer 74 is not necessarily a distinct metallic bonding layer with a definite thickness. In some cases, the solid-state bonding layer 74 is identified as a region where impurities or voids introduced during the process of solid-state bonding persist along the interface of the two metal layers.

As shown in FIG. 14, the solid-state bonding layer 74 includes a first bonding layer 74A and a second bonding layer 74B. The first bonding layer 74A is located between one of the two first coating layers 71 and the third coating layer 732 of the bonding layer 73 that faces the relevant first coating layer 71. The second bonding layer 74B is located between one of the two second coating layers 72 and the fourth coating layer 733 of the bonding layer 73 that faces the relevant second coating layer 72.

As shown in FIG. 14, in each bonding layer 73, the third coating layer 732 and the fourth coating layer 733 each include a first layer 751, a second layer 752, and a third layer 753. The first layer 751 covers the base layer 731. The first layer 751 contains nickel (Ni). The second layer 752 covers the first layer 751. The second layer 752 contains copper. In other words, the second layer 752 contains a metal contained in each of the two supporting layers 112 and the two conductive layers 12. Hence, the Vickers hardness of the first layer 751 is higher than that of the second layer 752. The third layer 753 covers the second layer 752. The third layer 753 faces a corresponding one of the two first coating layers 71 or a corresponding one of the two second coating layers 72. When the first coating layers 71 and the second coating layers 72 contain silver, the third layer 753 contains either silver or gold. When the first coating layers 71 and the second coating layers 72 contain gold, the third layer 753 contains silver. When the third layer 753 contains silver, the thermal conductivity of the third layer 753 is higher than that of the second layer 752.

As shown in FIG. 14, the first bonding layer 74A is located between one of the first coating layers 71 and the third layer 753 of the third coating layer 732 that faces the relevant first coating layer 71. The second bonding layer 74B is located between one of the two second coating layers 72 and the third layer 753 of the fourth coating layer 733 that faces the relevant second coating layer 72.

Along with the formation of the solid-state bonding layer 74, part of the metal contained in the second layer 752 diffuses mainly into the third layer 753. Here, the diffusion from the second layer 752 into each of the third layer 753, the first coating layer 71, and the second coating layer 72 is more extensive than that from the first layer 751. The third coating layer 732 and the fourth coating layer 733 each including a first layer 751, a second layer 752, and a third layer 753 may be formed by sputtering to sequentially deposit a plurality of thin films of metals on either side of the base layer 731 in the first direction z.

As shown in FIGS. 5 and 9, each semiconductor element 21 is mounted on either the first conductive layer 12A or the second conductive layer 12B. The semiconductor elements 21 may be MOSFETS (metal-oxide-semiconductor field-effect transistors). Alternatively, the semiconductor elements 21 may be other switching elements, such as IGBTs (insulated gate bipolar transistors), or diodes. In the following description of the semiconductor device A10, the semiconductor elements 21 are n-channel vertical MOSFETs. Each semiconductor element 21 has a compound semiconductor substrate. The composition of the compound semiconductor substrate includes a silicon carbide (SiC).

As shown in FIG. 5, the semiconductor elements 21 of the semiconductor device A10 include a plurality of first elements 21A and a plurality of second elements 21B. The second elements 21B are identical in configuration to the first elements 21A. The first elements 21A are mounted on the obverse surface 121 of the first conductive layer 12A. The first elements 21A are arranged along the third direction y. The second elements 21B are mounted on the obverse surface 121 of the second conductive layer 12B. The second elements 21B are arranged along the third direction y.

As shown in FIGS. 5, 10, and 11, each semiconductor element 21 includes a first electrode 211, a second electrode 212, a third electrode 213, and a fourth electrode 214.

As shown in FIGS. 10 and 11, the first electrode 211 faces the first conductive layer 12A or the second conductive layer 12B. The first electrode 211 passes the electric current corresponding to the power before conversion by the semiconductor element 21. That is, the first electrode 211 is the drain electrode of the semiconductor element 21.

As shown in FIGS. 10 and 11, the second electrode 212 is located opposite first electrode 211 in the first direction z. The second electrode 212 passes the electric current corresponding to the power converted by the semiconductor element 21. That is, the second electrode 212 is the source electrode of the semiconductor element 21.

As shown in FIGS. 10 and 11, the third electrode 213 is located on the same side as the second electrode 212 in the first direction z. The third electrode 213 receives the gate voltage applied to drive the semiconductor element 21. That is, the third electrode 213 is the gate electrode of the semiconductor element 21. As shown in FIG. 5, the third electrode 213 has a smaller area than the second electrode 212 as viewed in the first direction z.

As shown in FIG. 5, the fourth electrode 214 is located on the same side as the second electrode 212 in the first direction z and next to the third electrode 213 in the third direction y. The fourth electrode 214 is at the same potential as the second electrode 212.

As shown in FIGS. 10 and 11, a conductive bonding layer 29 is provided between the first conductive layer 12A and the first electrodes 211 of the relevant semiconductor elements 21 and between the second conductive layer 12B and the first electrodes 211 of the relevant semiconductor elements 21. The conductive bonding layer 29 is made of solder, for example. Alternatively, the conductive bonding layer 29 may contain sintered metal particles. The first electrodes 211 of the first elements 21A are electrically bonded to the obverse surface 121 of the first conductive layer 12A via the conductive bonding layer 29. This electrically connects the first electrodes 211 of the first elements 21A to the first conductive layer 12A. The first electrodes 211 of the second elements 21B are electrically bonded to the obverse surface 121 of the second conductive layer 12B via the conductive bonding layer 29. This electrically connects the first electrodes 211 of the second elements 21B to the second conductive layer 12B.

As shown in FIGS. 3 and 9, the first input terminal 13 is located opposite the second conductive layer 12B in the second direction x across the first conductive layer 12A and is connected to the first conductive layer 12A. Thus, the first input terminal 13 is electrically connected to the first electrodes 211 of the first elements 21A via the first conductive layer 12A. The first input terminal 13 is a P terminal (positive terminal) to which DC power supply voltage to be converted is applied. The first input terminal 13 extends in the second direction x from the first conductive layer 12A. The first input terminal 13 includes a covered portion 13A and an exposed portion 13B. As shown in FIG. 9, the covered portion 13A is connected to the first conductive layer 12A and is covered with the sealing resin 50. The covered portion 13A is flush with the obverse surface 121 of the first conductive layer 12A. The exposed portion 13B extends in the second direction x from the covered portion 13A and is exposed from the sealing resin 50.

As shown in FIGS. 3 and 8, the output terminal 14 is located opposite the first conductive layer 12A in the second direction x across the second conductive layer 12B and is connected to the second conductive layer 12B. Thus, the output terminal 14 is electrically connected to the first electrodes 211 of the second elements 21B via the second conductive layer 12B. The output terminal 14 outputs the AC power converted by the semiconductor elements 21. In the semiconductor device A10, the output terminal 14 includes two regions that are spaced apart from each other in the third direction y. Alternatively, the output terminal 14 may be composed of a single structure not including two separate regions. The output terminal 14 includes a covered portion 14A and an exposed portion 14B. As shown in FIG. 8, the covered portion 14A is connected to the second conductive layer 12B and is covered with the sealing resin 50. The covered portion 14A is flush with the obverse surface 121 of the second conductive layer 12B. The exposed portion 14B extends in the second direction x from the covered portion 14A and is exposed from the sealing resin 50.

As shown in FIGS. 3 and 8, the second input terminal 15 is located on the same side as the first input terminal 13 in the second direction x with respect to the first and second conductive layers 12A and 12B and is spaced apart from the first and second conductive layers 12A and 12B. The second input terminal 15 is electrically connected to the second electrodes 212 of the second elements 21B. The second input terminal 15 is an N terminal (negative terminal) to which DC power supply voltage to be converted is applied. The second input terminal 15 includes two regions spaced apart from each other in the third direction y. The first input terminal 13 is located between the two regions in the third direction y. The second input terminal 15 includes a covered portion 15A and an exposed portion 15B. As shown in FIG. 8, the covered portion 15A is spaced apart from first conductive layer 12A and is covered with the sealing resin 50. The exposed portion 15B extends in the second direction x from the covered portion 15A and is exposed from the sealing resin 50.

The two control wirings 60 form portions of the conduction paths connecting each of the first signal terminal 161, the second signal terminal 162, the third signal terminal 171, the fourth signal terminal 172, the fifth signal terminals 181, and the sixth signal terminals 182 to the semiconductor elements 21. As shown in FIGS. 3 to 5, the two control wirings 60 include a first wiring 601 and a second wiring 602. In the second direction x, the first wiring 601 is located between the plurality of first elements 21A and the first and second input terminals 13 and 15. The first wiring 601 is bonded to the obverse surface 121 of the first conductive layer 12A. The first wiring 601 also forms a portion of a conduction path connecting the seventh signal terminal 19 and the first conductive layer 12A. In the second direction x, the second wiring 602 is located between the plurality of second elements 21B and the output terminal 14. The second wiring 602 is bonded to the obverse surface 121 of the second conductive layer 12B. As shown in FIGS. 10 and 11, the two control wirings 60 each include an insulating layer 61, a plurality of wiring layers 62, an intermediate layer 63, and a plurality of sleeves 64. The control wirings 60 are covered with the sealing resin 50, except for a portion of each sleeve 64.

As shown in FIGS. 10 and 11, the insulating layer 61 includes portions interposed between the respective wiring layers 62 and the intermediate layer 63 in the first direction z. The insulating layer 61 is made of a ceramic material, for example. Alternatively, the insulating layer 61 may be made of an insulating resin sheet rather than a ceramic material.

As shown in FIGS. 10 and 11, the plurality of wiring layers 62 are located on the first side of the insulating layer 61 in the first direction z. The composition of the wiring layers 62 includes copper. As shown in FIG. 5, the plurality of wiring layers 62 include a first wiring layer 621, a second wiring layer 622, two third wiring layers 623, a fourth wiring layer 624, and a fifth wiring layer 625. The third wiring layers 623 are next to each other in the third direction y.

As shown in FIGS. 10 and 11, the intermediate layer 63 is located opposite the plurality of wiring layers 62 in the first direction z across the insulating layer 61. The composition of the intermediate layer 63 includes copper. The intermediate layer 63 of the first wiring 601 is bonded to the obverse surface 121 of the first conductive layer 12A by a first bonding layer 68. The intermediate layer 63 of the second wiring 602 is bonded to the obverse surface 121 of the second conductive layer 12B by a first bonding layer 68. The material of the first bonding layer 68 may be either conductive or non-conductive. The first bonding layer 68 is made of solder, for example.

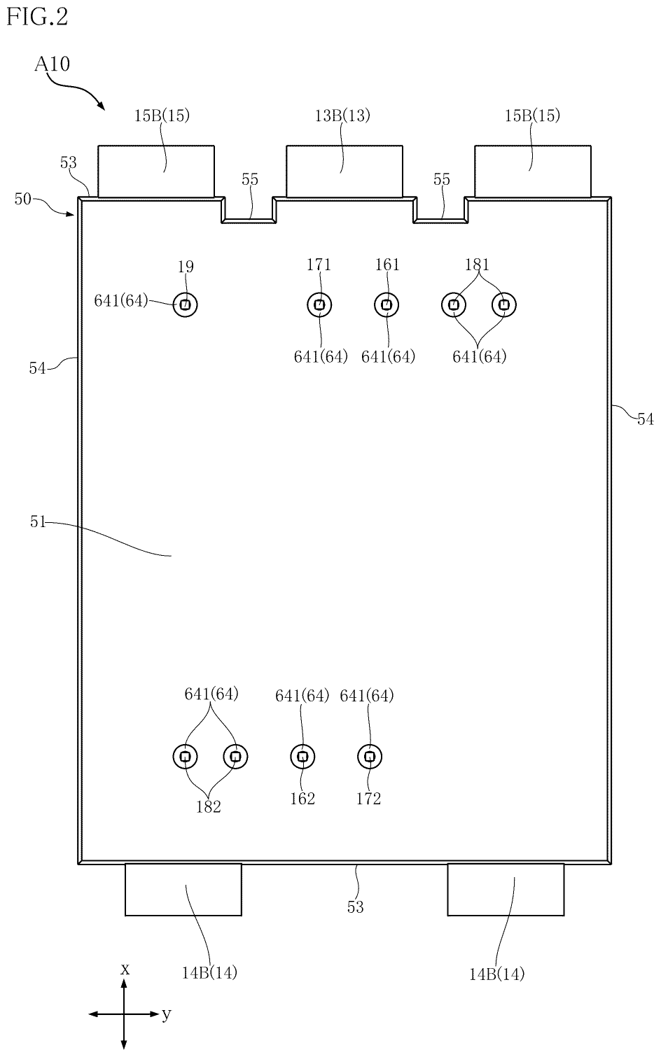

As shown in FIGS. 10 and 11, each sleeve 64 is bonded to one of the wiring layers 62 by a second bonding layer 69. The sleeves 64 are made of a conductive material, such as metal. Each sleeve 64 is a tubular structure extending in the first direction z. Each sleeve 64 is electrically bonded to one of the wiring layers 62 at one end. As shown in FIGS. 2 and 9, each sleeve 64 has an end surface 641 at the other end that is exposed above the top surface 51 of the sealing resin 50. The second bonding layer 69 is conductive. The second bonding layer 69 is made of solder, for example.

As shown in FIG. 4, one of the two thermistors 22 is electrically bonded to the two third wiring layers 623 of the first wiring 601. As shown in FIG. 4, the other thermistor 22 is electrically bonded to the two third wiring layers 623 of the second wiring 602. The two thermistors 22 are negative temperature coefficient (NTC) thermistors, for example. An NTC thermistor has a resistance that gradually decreases as the temperature increases. The two thermistors 22 are used as temperature sensors of the semiconductor device A10.

As shown in FIG. 1, the first to seventh signal terminals 161, 162, 171, 172, 181, 182, and 19 are made of metal pins extending in the first direction z. These signal terminals protrude from the top surface 51, which will be described later, of the sealing resin 50. In addition, these signal terminals are press-fitted into the respective sleeves 64 of the control wirings 60. That is, each signal terminal is supported by one of the sleeves 64 and electrically connected to one of the wiring layers 62.

As shown in FIGS. 5 and 10, the first signal terminal 161 is fitted into the sleeve 64 that is bonded to the first wiring layer 621 of the first wiring 601, among the plurality of sleeves 64 of the control wirings 60. In this way, the first signal terminal 161 is supported by the sleeve 64 and electrically connected to the first wiring layer 621 of the first wiring 601. Hence, the first signal terminal 161 is electrically connected also to the third electrodes 213 of the first elements 21A. The gate voltage for driving the first elements 21A is applied to the first signal terminal 161.

As shown in FIGS. 5 and 11, the second signal terminal 162 is fitted into the sleeve 64 that is bonded to the first wiring layer 621 of the second wiring 602, among the plurality of sleeves 64 of the control wirings 60. In this way, the second signal terminal 162 is supported by the sleeve 64 and electrically connected to the first wiring layer 621 of the second wiring 602. The second signal terminal 162 is electrically connected also to the third electrodes 213 of the second elements 21B. The gate voltage for driving the second elements 21B is applied to the second signal terminal 162.

As shown in FIG. 2, the third signal terminal 171 is located next to the first signal terminal 161 in the third direction y. As shown in FIG. 5, the third signal terminal 171 is fitted into the sleeve 64 that is bonded to the second wiring layer 622 of the first wiring 601, among the plurality of sleeves 64 of the control wirings 60. In this way, the third signal terminal 171 is supported by the sleeve 64 and electrically connected to the second wiring layer 622 of the first wiring 601. The third signal terminal 171 is electrically connected also to the fourth electrodes 214 of the first elements 21A. third signal terminal 171 receives corresponding to the maximum current flowing through the fourth electrodes 214 of the first elements 21A.

As shown in FIG. 2, the fourth signal terminal 172 is located next to the second signal terminal 162 in the third direction y. As shown in FIG. 5, the fourth signal terminal 172 is fitted into the sleeve 64 that is bonded to the second wiring layer 622 of the second wiring 602, among the plurality of sleeves 64 of the control wirings 60. In this way, the fourth signal terminal 172 is supported by the sleeve 64 and electrically connected to the second wiring layer 622 of the second wiring 602. The fourth signal terminal 172 is electrically connected also to the fourth electrodes 214 of the second elements 21B. The fourth signal terminal 172 receives a voltage corresponding to the maximum current flowing through the fourth electrodes 214 of the second elements 21B.

As shown in FIG. 2, the two fifth signal terminals 181 are located opposite the third signal terminal 171 in the third direction y across the first signal terminal 161. The two fifth signal terminals 181 are next to each other in the third direction y. As shown in FIG. 5, each fifth signal terminal 181 is fitted into the sleeve 64 that is bonded to one of the two third wiring layers 623 of the first wiring 601, among the plurality of sleeves 64 of the control wirings 60. In this way, each fifth signal terminal 181 is supported by the sleeve 64 and electrically connected to the corresponding one of third wiring layers 623 of the first wiring 601. Each fifth signal terminal 181 is electrically connected also to one of the two thermistors 22 that is electrically bonded to the two third wiring layers 623 of the first wiring 601.

As shown in FIG. 2, the two sixth signal terminals 182 are located opposite the fourth signal terminal 172 in the third direction y across the second signal terminal 162. The two sixth signal terminals 182 are next to each other in the third direction y. As shown in FIG. 5, each sixth signal terminal 182 is fitted into the sleeve 64 that is bonded to one of the two third wiring layers 623 of the second wiring 602, among the plurality of sleeves 64 of the control wirings 60. In this way, each sixth signal terminal 182 is supported by the sleeve 64 and electrically connected to the corresponding one of third wiring layers 623 of the second wiring 602. Each sixth signal terminal 182 is electrically connected also to one of the two thermistors 22 that is electrically bonded to the two third wiring layers 623 of the second wiring 602.

As shown in FIG. 2, the seventh signal terminal 19 is located opposite the first signal terminal 161 in the third direction y across third signal terminal 171. As shown in FIG. 5, the seventh signal terminal 19 is fitted into the sleeve 64 that is bonded to the fifth wiring layer 625 of the first wiring 601, among the plurality of sleeves 64 of the two control wirings 60. In this way, the seventh signal terminal 19 is supported by the sleeve 64 and electrically connected to the fifth wiring layer 625 of the first wiring 601. The seventh signal terminal 19 is electrically connected also to the first conductive layer 12A. The seventh signal terminal 19 receives a voltage corresponding to the DC power input to the first input terminal 13 and the second input terminal 15.

As shown in FIG. 5, a plurality of first wires 41 are electrically bonded to the third electrodes 213 of the first elements 21A and the fourth wiring layer 624 of the first wiring 601. As shown in FIG. 5, a plurality of third wires 43 are electrically bonded to the fourth wiring layer 624 of the first wiring 601 and the first wiring layer 621 of the first wiring 601. Thus, the first signal terminal 161 is electrically connected to the third electrodes 213 of the first elements 21A. The composition of the first wires 41 and the third wires 43 includes gold. Alternatively, the composition of the first wires 41 and the third wires 43 may include copper or aluminum.

As shown in FIG. 5, a plurality of first wires 41 are electrically bonded to the third electrodes 213 of the second elements 21B and the fourth wiring layer 624 of the second wiring 602. As shown in FIG. 5, a plurality of third wires 43 are electrically bonded to the fourth wiring layer 624 of the second wiring 602 and the first wiring layer 621 of the second wiring 602. Thus, the second signal terminal 162 is electrically connected to the third electrodes 213 of the second elements 21B.

As shown in FIG. 5, a plurality of second wires 42 are electrically bonded to the fourth electrodes 214 of the first elements 21A and the second wiring layer 622 of the first wiring 601. Thus, the third signal terminal 171 is electrically connected to the fourth electrodes 214 of the first elements 21A. As shown in FIG. 5, a plurality of second wires 42 are electrically bonded to the fourth electrodes 214 of the second elements 21B and the second wiring layer 622 of the second wiring 602. Thus, the fourth signal terminal 172 is electrically connected to the fourth electrodes 214 of the second elements 21B. The composition of the second wires 42 includes gold. Alternatively, the composition of the second wires 42 may include copper or aluminum.

As shown in FIG. 5, a fourth wire 44 is electrically bonded to the fifth wiring layer 625 of the first wiring 601 and the obverse surface 121 of the first conductive layer 12A. Thus, the seventh signal terminal 19 is electrically connected to the first conductive layer 12A. The composition of the fourth wire 44 includes gold. Alternatively, the composition of the fourth wire 44 may include copper or aluminum.

As shown in FIGS. 5 and 10, the first conductive member 31 is electrically bonded to the second electrodes 212 of the first elements 21A and the obverse surface 121 of the second conductive layer 12B. This electrically connects the second electrodes 212 of the first elements 21A to the second conductive layer 12B. The composition of the first conductive member 31 includes copper. The first conductive member 31 is a metal clip. As shown in FIG. 5, the first conductive member 31 includes a body 311, a plurality of first bonding portions 312, a plurality of first connecting portions 313, a second bonding portion 314, and a second connecting portion 315.

The body 311 is the major part of the first conductive member 31. As shown in FIG. 5, the body 311 extends in the third direction y. As shown in FIG. 9, the body 311 extends across the gap between the first conductive layer 12A and the second conductive layer 12B.

As shown in FIG. 10, the first bonding portions 312 are bonded to the second electrodes 212 of the first elements 21A. Each first bonding portion 312 faces the second electrode 212 of a first element 21A.

As shown in FIG. 5, the first connecting portions 313 connect the body 311 and the first bonding portions 312. The first connecting portions 313 are spaced apart from each other in the third direction y. As shown in FIG. 9, each first connecting portion 313 as viewed in the third direction y is inclined away from the obverse surface 121 of the first conductive layer 12A as it approaches the body 311 from the first bonding portion 312.

As shown in FIGS. 5 and 9, the second bonding portion 314 is bonded to the obverse surface 121 of the second conductive layer 12B. The second bonding portion 314 faces the obverse surface 121. The second bonding portion 314 extends in the third direction y. The dimension of the second bonding portion 314 in the third direction y is equal to the dimension of the body 311 in the third direction y.

As shown in FIGS. 5 and 9, the second connecting portion 315 connects the body 311 and the second bonding portion 314. As viewed in the third direction y, the second connecting portion 315 is inclined away from the obverse surface 121 of the second conductive layer 12B as it approaches the body 311 from the second bonding portion 314. The dimension of the second connecting portion 315 in the third direction y is equal to the dimension of the body 311 in the third direction y.

As shown in FIGS. 9, 10, and 13, the semiconductor device A10 additionally includes a first conductive bonding layer 33. The first conductive bonding layer 33 is disposed between the second electrode 212 of each first element 21A and the corresponding first bonding portion 312. The first conductive bonding layer 33 electrically joins the second electrode 212 of each first element 21A and the corresponding first bonding portion 312. The first conductive bonding layer 33 is made of solder, for example. Alternatively, the first conductive bonding layer 33 may contain sintered metal particles.

As shown in FIG. 9, the semiconductor device A10 additionally includes a second conductive bonding layer 34. The second conductive bonding layer 34 is disposed between the obverse surface 121 of the second conductive layer 12B and the second bonding portion 314. The second conductive bonding layer 34 electrically joins the obverse surface 121 and the second bonding portion 314. The second conductive bonding layer 34 is made of solder, for example. Alternatively, the second conductive bonding layer 34 may contain sintered metal particles.

As shown in FIGS. 4 and 11, the second conductive member 32 is electrically bonded to the second electrodes 212 of the second elements 21B and the covered portion 15A of the second input terminal 15. Thus, the second electrodes 212 of the second elements 21B are electrically connected to the second input terminal 15. The composition of the second conductive member 32 includes copper. The second conductive member 32 is a metal clip. As shown in FIG. 4, the second conductive member 32 includes two bodies 321, a plurality of third bonding portions 322, a plurality of third connecting portions 323, two fourth bonding portions 324, two fourth connecting portions 325, a plurality of intermediate portions 326, and a plurality of cross beams 327.

As shown in FIG. 4, the two bodies 321 are spaced apart from each other in the third direction y. The bodies 321 extend in the second direction x. As shown in FIG. 8, the bodies 321 are disposed parallel to the obverse surfaces 121 of the first conductive layer 12A and the second conductive layer 12B. The bodies 321 are located farther from the respective obverse surfaces 121 than the body 311 of the first conductive member 31.

As shown in FIG. 4, the intermediate portions 326 are spaced apart from each other in the third direction y and are located between the two bodies 321 in the third direction y. The intermediate portions 326 extend in the second direction x. The dimension of each intermediate portion 326 in the second direction x is smaller than the dimension of each body 321 in the second direction x.

As shown in FIG. 11, the third bonding portions 322 are bonded to the second electrodes 212 of the respective second elements 21B. Each third bonding portion 322 faces the second electrode 212 of the corresponding second element 21B.

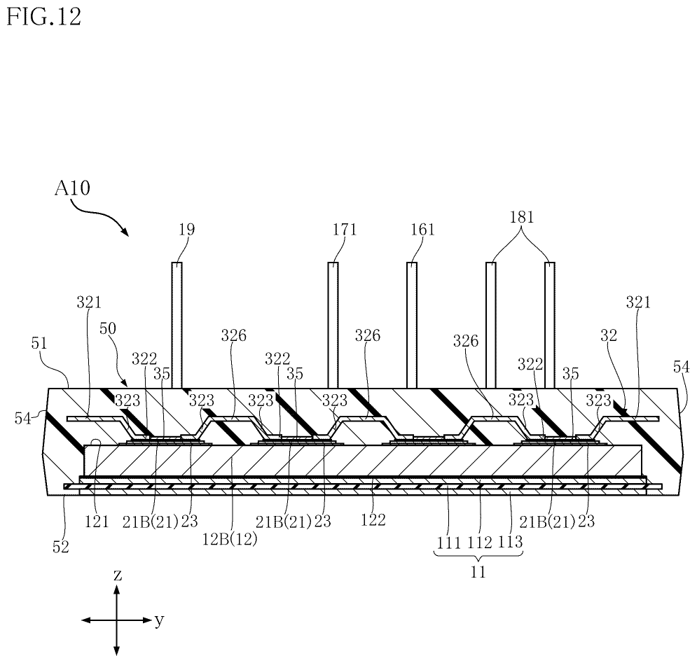

As shown in FIGS. 4 and 12, one third connecting portion 323 is connected at each end of each third bonding portion 322 in the third direction y. Each third connecting portion 323 is also connected to one of the two bodies 321 or one of the intermediate portions 326. As viewed in the second direction x, each third connecting portion 323 is inclined away from the obverse surface 121 of the second conductive layer 12B as it approaches the corresponding body 321 or intermediate portion 326 from the third bonding portion 322.

As shown in FIGS. 4 and 8, the two fourth bonding portions 324 are bonded to the covered portion 15A of the second input terminal 15. The two fourth bonding portions 324 face the covered portion 15A.

As shown in FIGS. 4 and 8, each fourth connecting portion 325 connects a body 321 and a fourth bonding portion 324. As viewed in the third direction y, each fourth connecting portion 325 is inclined away from the obverse surface 121 of the first conductive layer 12A as it approaches the corresponding body 321 from the fourth bonding portion 324.

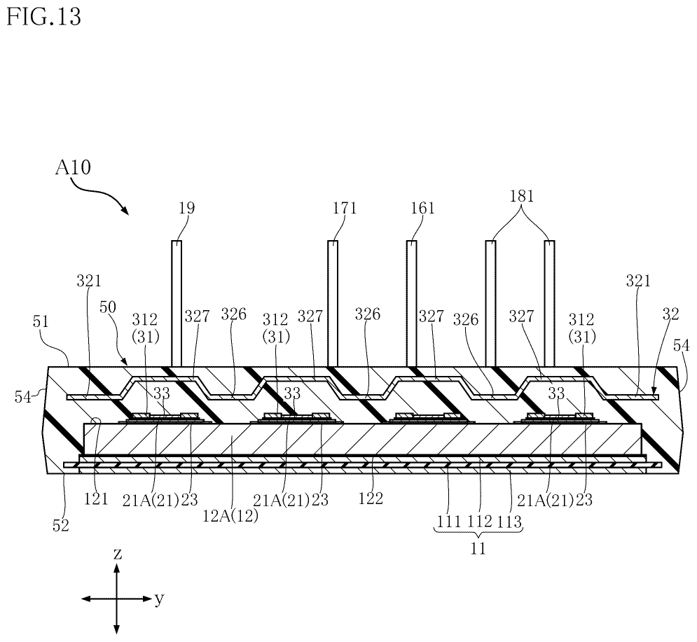

As shown in FIGS. 4 and 13, the cross beams 327 are arranged along the third direction y. As viewed in the first direction z, each cross beam 327 includes a region that overlaps with a first bonding portion 312 of the first conductive member 31. Among the plurality of cross beams 327, each cross beam 327 that is not the outermost one in the third direction y is connected to an intermediate portion 326 at each end in the third direction y. Each of the other two cross beams 327 is connected to a body 321 at one end in the third direction y and to an intermediate portion 326 at the other end. As viewed in the second direction x, each cross beam 327 protrudes in the first direction z toward the side that the obverse surface 121 of the first conductive layer 12A faces.

As shown in FIGS. 9, 11, and 12, the semiconductor device A10 additionally includes a third conductive bonding layer 35. The third conductive bonding layer 35 is disposed between the second electrode 212 of each second element 21B and the corresponding third bonding portion 322. The third conductive bonding layer 35 electrically joins the second electrode 212 of each second element 21B and the corresponding third bonding portion 322. The third conductive bonding layer 35 is made of solder, for example. Alternatively, the third conductive bonding layer 35 may contain sintered metal particles.

As shown in FIG. 8, the semiconductor device A10 additionally includes a fourth conductive bonding layer 36. The fourth conductive bonding layer 36 is disposed between the covered portion 15A of the second input terminal 15 and each fourth bonding portion 324. The fourth conductive bonding layer 36 electrically joins the covered portion 15A and each fourth bonding portion 324. The fourth conductive bonding layer 36 is made of solder, for example. Alternatively, the fourth conductive bonding layer 36 may contain sintered metal particles.

As shown in FIGS. 8, 9, 12, and 13, the sealing resin 50 covers the two supporting layers 112, the two conductive layers 12, the semiconductor elements 21, the first conductive member 31, and the second conductive member 32. The sealing resin 50 also covers a portion of each of the first input terminal 13, the output terminal 14, and the second input terminal 15. The sealing resin 50 is electrically insulating. The sealing resin 50 is made of a material containing a black epoxy resin, for example. As shown in FIGS. 2 and 6 to 9, the sealing resin 50 has a top surface 51, a bottom surface 52, two first side surfaces 53, two second side surfaces 54, and two recessed portions 55.

As shown in FIGS. 8 and 9, the top surface 51 faces the same side as the obverse surfaces 121 of the respective conductive layers 12 in the first direction z. As shown in FIGS. 8 and 9, the bottom surface 52 faces away from the top surface 51 in the first direction z. As shown in FIG. 7, the heat-dissipating layer 113 is exposed from the bottom surface 52.

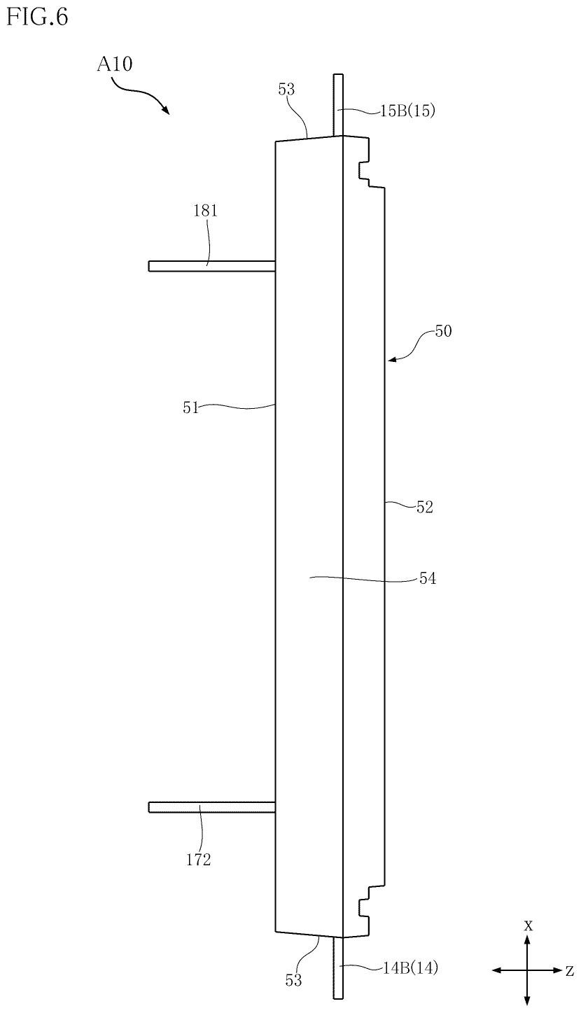

As shown in FIGS. 2 and 6, the two first side surfaces 53 are spaced apart from each other in the second direction x. Each first side surface 53 faces in the second direction x and extends in the third direction y. Each first side surface 53 is connected to the top surface 51. The exposed portion 13B of the first input terminal 13 and the exposed portion 15B of the second input terminal 15 protrude from one of the first side surfaces 53. The exposed portion 14B of the output terminal 14 protrudes from the other first side surface 53.

As shown in FIGS. 2 and 7, the two second side surfaces 54 are spaced apart from each other in the third direction y. The two second side surfaces 54 face away from each other in the third direction y and extend in the second direction x. Each second side surface 54 is connected to the top surface 51 and the bottom surface 52.

As shown in FIGS. 2 and 7, the two recessed portions 55 are recessed in the second direction x from the first side surface 53 from which the exposed portion 13B of the first input terminal 13 and the exposed portion 15B of the second input terminal 15 protrude. Each recessed portion 55 extends in the first direction z from the top surface 51 to the bottom surface 52. The two recessed portions 55 are located on the opposite sides of the first input terminal 13 in the third direction y.

Next, advantages of the semiconductor device A10 will be described.

The semiconductor device A10 includes a supporting layer 112, a conductive layer 12, a semiconductor element 21 bonded to the conductive layer 12, a first coating layer 71 covering the supporting layer 112, a second coating layer 72 covering the conductive layer 12, and a bonding layer 73 bonding the first coating layer 71 and the second coating layer 72. The bonding layer 73 includes a base layer 731, a third coating layer 732, and a fourth coating layer 733. A solid-state bonding layer 74 is formed between the first coating layer 71 and the third coating layer 732 and between the second coating layer 72 and the fourth coating layer 733. The Vickers hardness of the base layer 731 is lower than the Vickers hardness of each of the supporting layer 112 and the conductive layer 12. With this configuration, the base layer 731 is more deformable than the supporting layer 112 and the conductive layer 12. Thus, when the conductive layer 12 is joined to the supporting layer 112 via the bonding layer 73 by solid-state bonding, a larger contact area is formed between the bonding layer 73 and each of the first coating layer 71 and the second coating layer 72. In other words, the solid-state bonding layer 74 forms a larger bonding area. This enables the solid-state bonding layer 74 to form a stronger metallic bond.

Additionally, in the semiconductor device A10, each of the third coating layer 732 and the fourth coating layer 733 of the bonding layer 73 includes a first layer 751, a second layer 752 and a third layer 753. The diffusion from the second layer 752 into each of the third layer 753, the first coating layer 71, and the second coating layer 72 is more extensive than that from the first layer 751. With this configuration, a solid-state bonding layer 74 forms at the interface between the first coating layer 71 and the third coating layer 732, and also at the interface between the second coating layer 72 and the fourth coating layer 733. Further, the first layer 751 functions as a barrier layer that regulates the diffusion from the second layer 752. This promotes the diffusion from the second layer 752 into each of the third layer 753, the first coating layer 71, and the second coating layer 72. This enables the solid-state bonding layer 74 to form a stronger metallic bond. The configuration described above therefore enables the semiconductor device A10 to form a stronger bond between the supporting layer 112 and the conductive layer 12 and improves the heat dissipation of the semiconductor device A10.

Preferably, the first coating layer 71, the second coating layer 72, the third layer 753 of the third coating layer 732, and the third layer 753 of the fourth coating layer 733 each contain either silver or gold. Silver and gold are both more prone to plastic flow than copper. Consequently, this configuration promotes the formation of the solid-state bonding layer 74.

For each of the third coating layer 732 and the fourth coating layer 733, the Vickers hardness of the first layer 751 is higher than that of the second layer 752. When joining the conductive layer 12 to the supporting layer 112 by solid-state bonding, the bonding layer 73 of this configuration reduces the bending force applied to the second layer 752 and the third layer 753 about an axis along a direction perpendicular to the first direction z. Thus, the compressive stress on the solid-state bonding layer 74 is more uniformly distributed. This contributes to the increased strength of the metallic bonding in the solid-state bonding layer 74.

The conductive layer 12 is thicker than the supporting layer 112. This configuration allows heat in the conductive layer 12 to conduct more easily in a direction perpendicular to the first direction z and thus improves thermal conductivity from the conductive layer 12 to the supporting layer 112.

The semiconductor device A10 additionally includes an insulating layer 111 located opposite the conductive layer 12 with respect to the supporting layer 112. The supporting layer 112 is bonded to the insulating layer 111. This configuration makes it possible to bond a heat-dissipating layer 113 to the insulating layer 111 such that the heat-dissipating layer 113 is located opposite the supporting layer 112 with respect to the insulating layer 111. In this way, the heat-dissipating layer 113 is electrically insulated from the conductive layer 12 and further improves the heat dissipation of the semiconductor device A10.

As viewed in the first direction z, the conductive layer 12 is enclosed in the peripheral edge 112A of the supporting layer 112. This configuration is effective in avoiding the edges of the conductive layer 12 from being bent in a direction perpendicular to the first direction z when the conductive layer 12 is joined to the supporting layer 112 via the bonding layer 73 by solid-state bonding. This consequently reduces the concentration of stress on the insulating layer 111 resulting from such bending. As a result, the risk of cracking in the insulating layer 111 is reduced.

The heat-dissipating layer 113 is thicker than the supporting layer 112. This configuration reduces the thermal stress imposed on the insulating layer 111 when the conductive layer 12 is joined to the supporting layer 112 via the bonding layer 73 by solid-state bonding. Additionally, this configuration increases the flexural rigidity of the overall substrate 11 including the insulating layer 111, the supporting layer 112, and the heat-dissipating layer 113 and thus prevents warping of the substrate 11.

### Second Embodiment

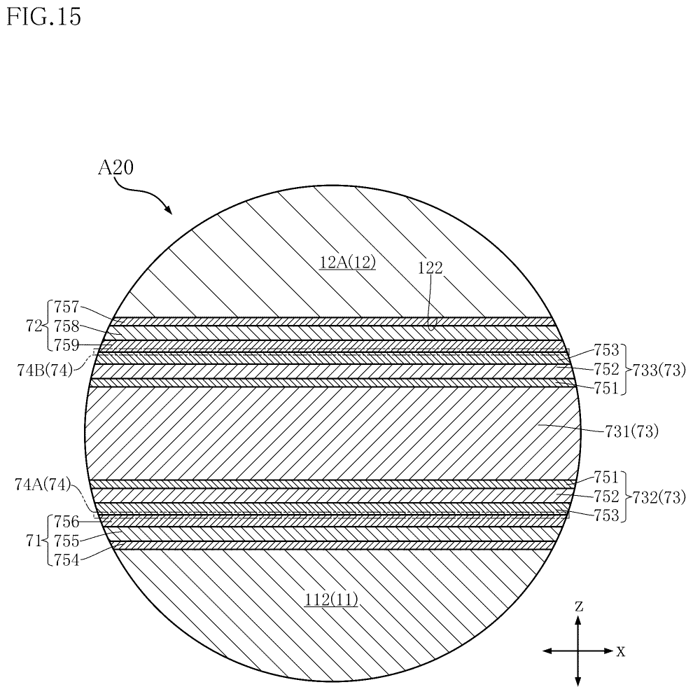

With reference to FIG. 15, a semiconductor device A20 according to a second embodiment of the present disclosure is described. In this figure, elements that are identical or similar to those of the semiconductor device A10 described above are indicated by the same reference numerals, and overlapping descriptions are omitted. The cross section shown in FIG. 15 is taken at the same position as the cross section of the semiconductor device A10 shown in FIG. 14.

The semiconductor device A20 differs from the semiconductor device A10 in the configuration of the two first coating layers 71 and the two second coating layers 72.

As shown in FIG. 15, each of the two first coating layers 71 includes a fourth layer 754, a fifth layer 755, and a sixth layer 756. The fourth layer 754 covers the supporting layer 112. The fourth layer 754 contains nickel. That is, the fourth layer 754 contains the same metal as that contained in the first layer 751 of the third coating layer 732 of a corresponding one of the two bonding layers 73. The fifth layer 755 covers the fourth layer 754. The fifth layer 755 contains copper. That is, the fifth layer 755 contains the same metal as that contained in the second layer 752 of the third coating layer 732. The sixth layer 756 covers the fifth layer 755. When the third layer 753 of the third coating layer 732 contains silver, the sixth layer 756 contains either silver or gold. When the third layer 753 of the third coating layer 732 contains gold, the sixth layer 756 contains silver. Thus, the diffusion from the fifth layer 755 into the sixth layer 756 is more extensive than that from the fourth layer 754.

As shown in FIG. 15, the first bonding layer 74A of the solid-state bonding layer 74 forms at the interface between the third layer 753 of the third coating layer 732 and the sixth layer 756. Each first coating layer 71, which includes a fourth layer 754, a fifth layer 755, and a sixth layer 756, is formed by sputtering to sequentially deposit a plurality of thin films of metals.

As shown in FIG. 15, each of the two second coating layers 72 includes a seventh layer 757, an eighth layer 758, and a ninth layer 759. The seventh layer 757 covers the reverse surface 122 of a corresponding one of the two conductive layers 12. The seventh layer 757 contains nickel. That is, the seventh layer 757 contains the same metal as that contained in the first layer 751 of the fourth coating layer 733 of a corresponding one of the two bonding layers 73. The eighth layer 758 covers the seventh layer 757. The eighth layer 758 contains copper. That is, the eighth layer 758 contains the same metal as that contained in the second layer 752 of the fourth coating layer 733. The ninth layer 759 covers the eighth layer 758. The ninth layer 759 faces the third layer 753 of the fourth coating layer 733. When the third layer 753 of the fourth coating layer 733 contains silver, the ninth layer 759 contains either silver or gold. When the third layer 753 of the fourth coating layer 733 contains gold, the ninth layer 759 contains silver. Thus, the diffusion from the eighth layer 758 into the ninth layer 759 is more extensive than that from the seventh layer 757.

As shown in FIG. 15, the second bonding layer 74B of the solid-state bonding layer 74 forms at the interface between the ninth layer 759 and the third layer 753 of the fourth coating layer 733. Each second coating layer 72, which includes a seventh layer 757, an eighth layer 758, and a ninth layer 759, is formed by sputtering to sequentially deposit a plurality of thin films of metals.

Next, advantages of the semiconductor device A20 will be described.

The semiconductor device A20 includes a supporting layer 112, a conductive layer 12, a semiconductor element 21 bonded to the conductive layer 12, a first coating layer 71 covering the supporting layer 112, a second coating layer 72 covering the conductive layer 12, and a bonding layer 73 bonding the first coating layer 71 and the second coating layer 72. The bonding layer 73 includes a base layer 731, a third coating layer 732, and a fourth coating layer 733. A solid-state bonding layer 74 is formed between the first coating layer 71 and the third coating layer 732 and between the second coating layer 72 and the fourth coating layer 733. The Vickers hardness of the base layer 731 is lower than the Vickers hardness of each of the supporting layer 112 and the conductive layer 12.

Additionally, in the semiconductor device A20, each of the third coating layer 732 and the fourth coating layer 733 of the bonding layer 73 includes a first layer 751, a second layer 752 and a third layer 753. The diffusion from the second layer 752 into each of the third layer 753, the first coating layer 71, and the second coating layer 72 is more extensive than that from the first layer 751. The configuration described above therefore enables the semiconductor device A20 to form a stronger bond between the supporting layer 112 and the conductive layer 12 and improves the heat dissipation of the semiconductor device A20. The semiconductor device A20 has a configuration in common with the semiconductor device A10, thereby achieving the same effect as the semiconductor device A10.

In the semiconductor device A20, the first coating layer 71 includes a fourth layer 754, a fifth layer 755, and a sixth layer 756. The fourth layer 754 contains the same metal as that contained in the first layer 751 of the third coating layer 732 of the bonding layer 73. The fifth layer 755 contains the same metal as that contained in the second layer 752 of the third coating layer 732. The diffusion from the fifth layer 755 into the sixth layer 756 is more extensive than that from the fourth layer 754. This configuration promotes the diffusion from the fifth layer 755 into each of the sixth layer 756 and the third layer 753 of the third coating layer 732 during the solid-state bonding of joining the conductive layer 12 to the supporting layer 112 via the bonding layer 73. This enables the first bonding layer 74A of the solid-state bonding layer 74 to form a stronger metallic bond.

In the semiconductor device A20, the second coating layer 72 includes a seventh layer 757, an eighth layer 758, and a ninth layer 759. The seventh layer 757 contains the same metal as that contained in the first layer 751 of the fourth coating layer 733 of the bonding layer 73. The eighth layer 758 contains the same metal as that contained in the second layer 752 of the fourth coating layer 733. The diffusion from the eighth layer 758 into the ninth layer 759 is more extensive than that from the seventh layer 757. This configuration promotes the diffusion from the eighth layer 758 into each of the ninth layer 759 of the second coating layer 72 and the third layer 753 of the fourth coating layer 733 during the solid-state bonding of joining the conductive layer 12 to the supporting layer 112 via the bonding layer 73. This enables the second bonding layer 74B of the solid-state bonding layer 74 to form a stronger metallic bond.

### Third Embodiment

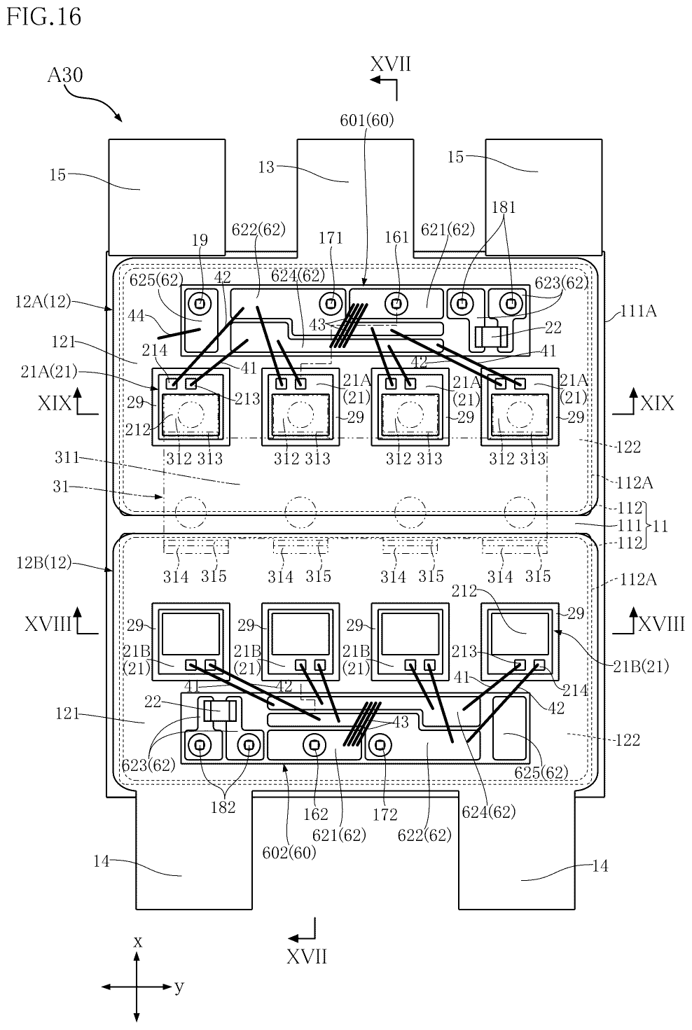

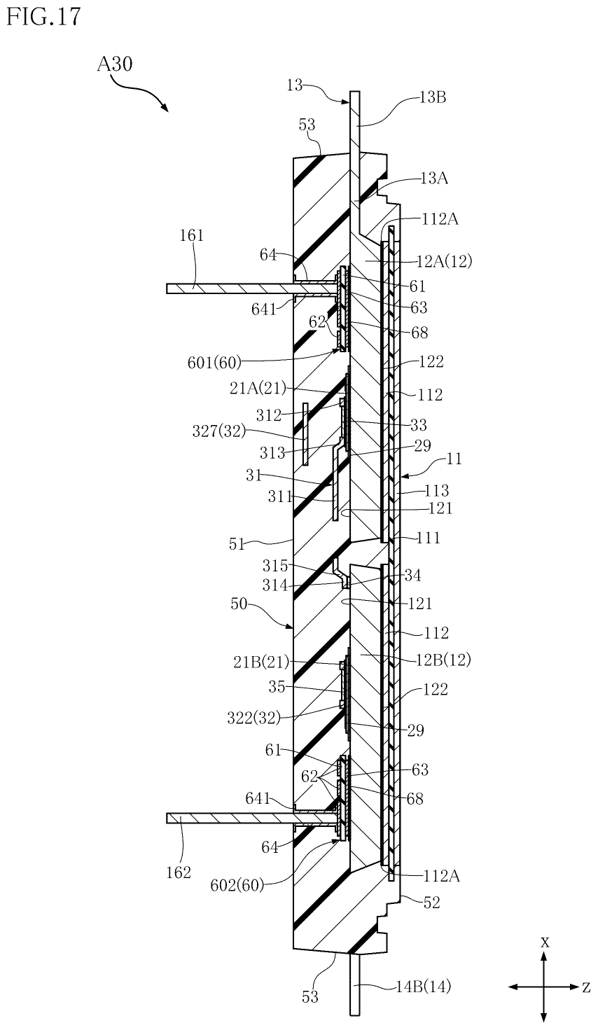

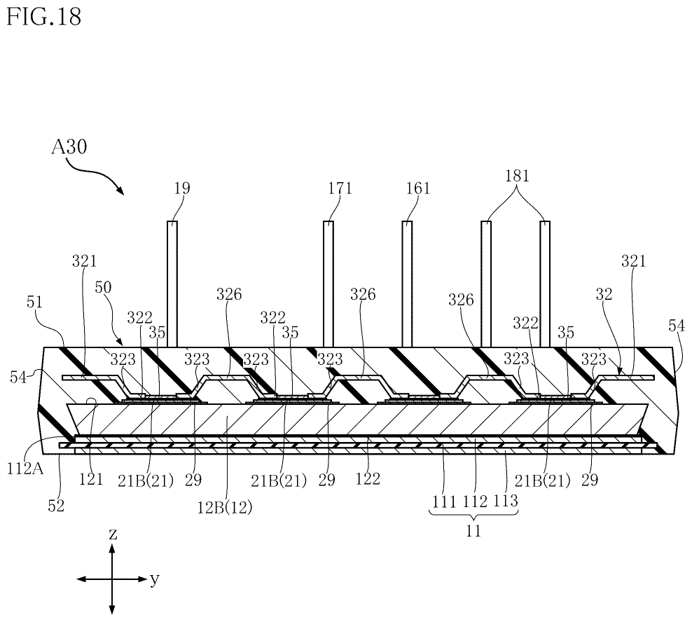

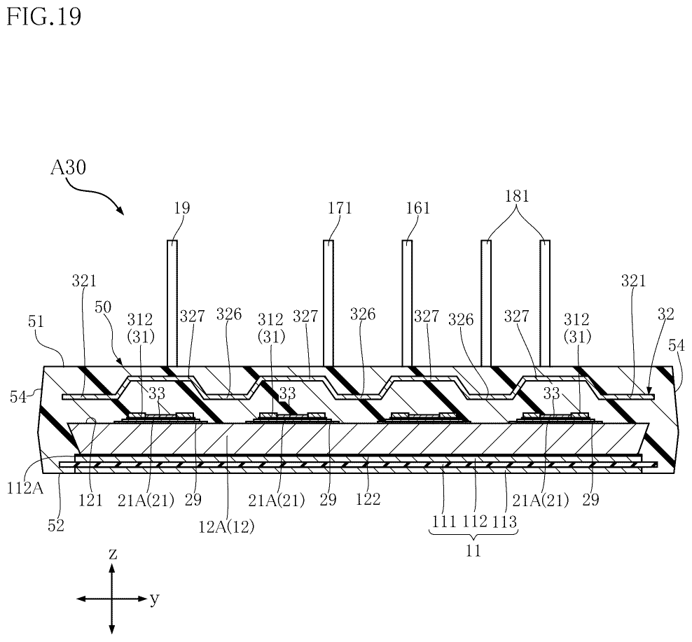

With reference to FIGS. 16 to 19, a semiconductor device A30 according to a third embodiment of the present disclosure is described. In this figure, elements that are identical or similar to those of the semiconductor device A10 described above are indicated by the same reference numerals, and overlapping descriptions are omitted. For the convenience of description, FIG. 16 shows the first conductive member 31 as transparent and omits the second conductive member 32 and the sealing resin 50. FIG. 16 shows the outline of the first conductive member 31 with an imaginary line.

The semiconductor device A30 differs from the semiconductor device A10 in the configuration of the two conductive layers 12.

As shown in FIGS. 16 to 19, for each of the two conductive layers 12, the obverse surface 121 is larger in area than the reverse surface 122. As viewed in the first direction z, the reverse surface 122 of each conductive layer 12 is enclosed in the peripheral edge 112A of a corresponding supporting layer 112. As viewed in the first direction z, the obverse surface 121 of either conductive layer 12 extends beyond the peripheral edge 112A of the supporting layer 112 to which the conductive layer 12 is joined. As viewed in the first direction z, the two conductive layers 12 are both enclosed in the peripheral edge 111A of the insulating layer 111.

Next, advantages of the semiconductor device A30 will be described.

The semiconductor device A30 includes a supporting layer 112, a conductive layer 12, and a semiconductor element 21 bonded to the conductive layer 12, a first coating layer 71 covering the supporting layer 112, a second coating layer 72 covering the conductive layer 12, and a bonding layer 73 bonding the first coating layer 71 and the second coating layer 72. The bonding layer 73 includes a base layer 731, a third coating layer 732, and a fourth coating layer 733. A solid-state bonding layer 74 is formed between the first coating layer 71 and the third coating layer 732 and between the second coating layer 72 and the fourth coating layer 733. The Vickers hardness of the base layer 731 is lower than the Vickers hardness of each of the supporting layer 112 and the conductive layer 12.

Additionally, in the semiconductor device A30, each of the third coating layer 732 and the fourth coating layer 733 of the bonding layer 73 includes a first layer 751, a second layer 752 and a third layer 753. The diffusion from the second layer 752 into each of the third layer 753, the first coating layer 71, and the second coating layer 72 is more extensive than that from the first layer 751. The configuration described above therefore the enables semiconductor device A30 to form a stronger bond between the supporting layer 112 and the conductive layer 12 and improves the heat dissipation of the semiconductor device A30. The semiconductor device A30 has a configuration in common with the semiconductor device A10, thereby achieving the same effect as the semiconductor device A10.

As viewed in the first direction z, the reverse surface 122 of the conductive layer 12 is enclosed in the peripheral edge 112A of the supporting layer 112. The obverse surface 121 of the conductive layer 12 faces the semiconductor element 21. The obverse surface 121 of the conductive layer 12 is larger in area than the reverse surface 122. This configuration allows the conductive layer 12 to have a larger obverse surface 121, while reducing the concentration of stress on the insulating layer 111 by preventing the edges of the conductive layer 12 from being bent in a direction perpendicular to the first direction z of the conductive layer 12 when the conductive layer 12 is joined to the supporting layer 112 via the bonding layer 73 by solid-state bonding y. This provides greater flexibility in selecting the location on the obverse surface 121 for bonding the semiconductor element 21.

### Fourth Embodiment

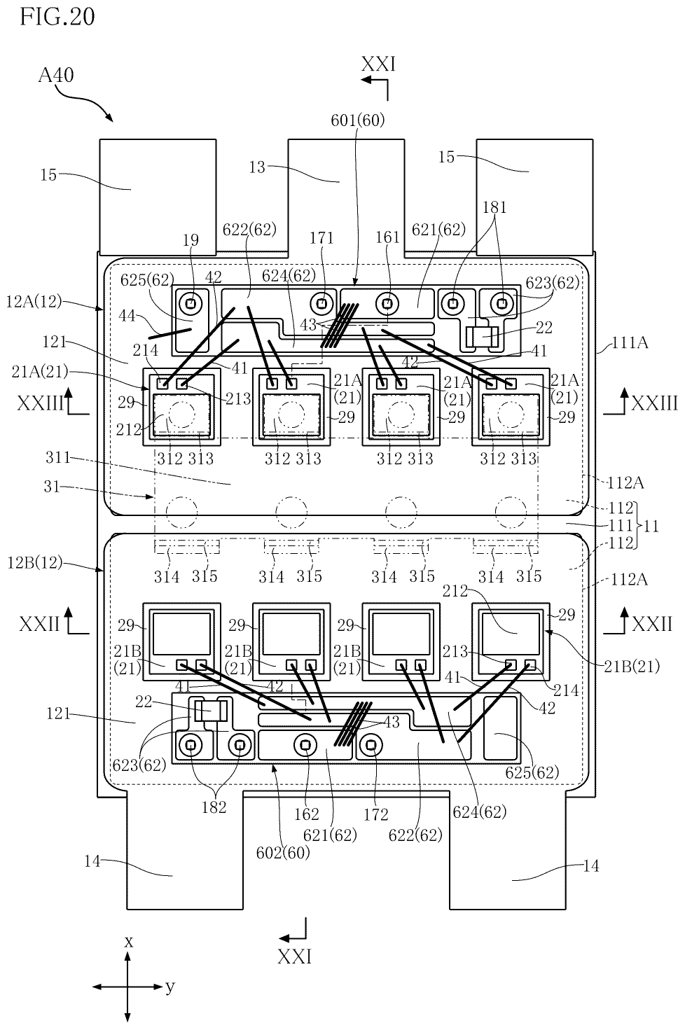

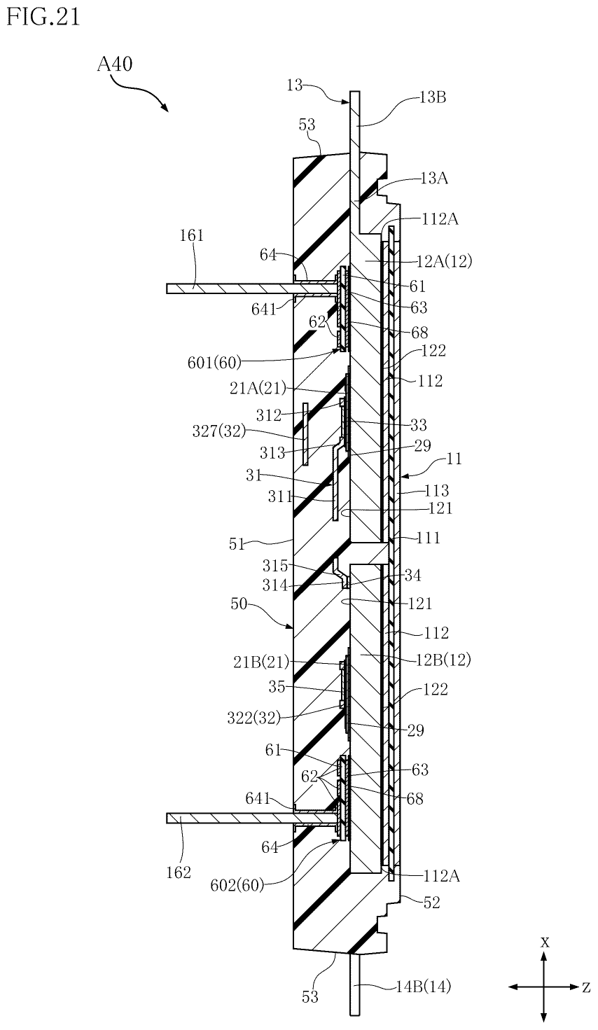

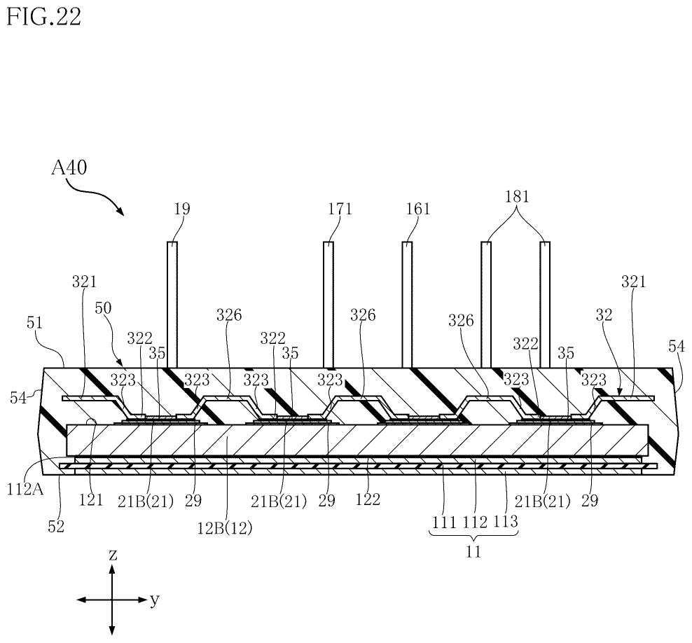

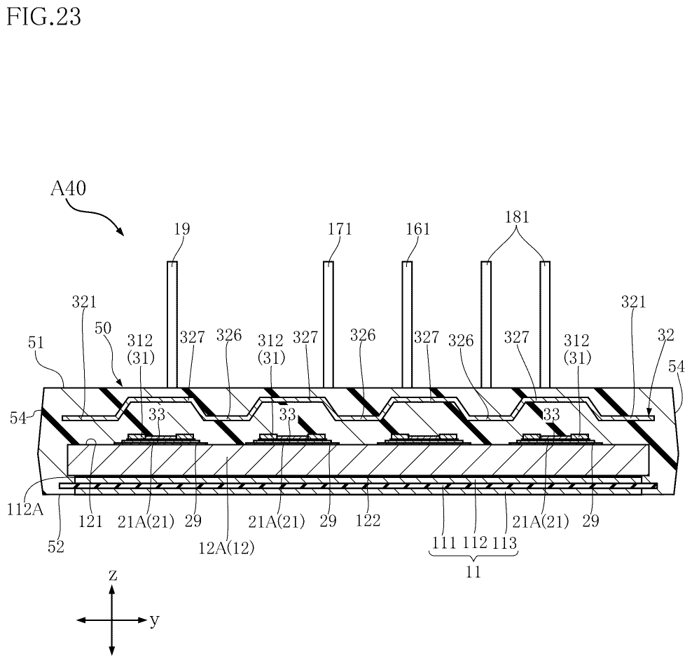

With reference to FIGS. 20 to 23, a semiconductor device A40 according to a fourth embodiment of the present disclosure is described. In this figure, elements that are identical or similar to those of the semiconductor device A10 described above are indicated by the same reference numerals, and overlapping descriptions are omitted. For the convenience of description, FIG. 20 shows the first conductive member 31 as transparent and omits the second conductive member 32 and the sealing resin 50. FIG. 20 shows the outline of the first conductive member 31 with an imaginary line.

The semiconductor device A40 differs from the semiconductor device A10 in the configuration of the two conductive layers 12.

As shown in FIGS. 20 to 23, each of the conductive layers 12 as viewed in the first direction x has an obverse surface 121 and a reverse surface 122 both of which extend beyond the peripheral edge 112A of the supporting layer 112 to which the conductive layer 12 is bonded. For each of the two conductive layers 12, the area of the reverse surface 122 is equal to the area of the obverse surface 121. As viewed in the first direction z, the two conductive layers 12 are both enclosed in the peripheral edge 111A of the insulating layer 111.

Next, advantages of the semiconductor device A40 will be described.

The semiconductor device A40 includes a supporting layer 112, a conductive layer 12, a semiconductor element 21 bonded to the conductive layer 12, a first coating layer 71 covering the supporting layer 112, a second coating layer 72 covering the conductive layer 12, and a bonding layer 73 bonding the first coating layer 71 and the second coating layer 72. The bonding layer 73 includes a base layer 731, a third coating layer 732, and a fourth coating layer 733. A solid-state bonding layer 74 is formed between the first coating layer 71 and the third coating layer 732 and between the second coating layer 72 and the fourth coating layer 733. The Vickers hardness of the base layer 731 is lower than the Vickers hardness of each of the supporting layer 112 and the conductive layer 12.

Additionally, in the semiconductor device A40, each of the third coating layer 732 and the fourth coating layer 733 of the bonding layer 73 includes a first layer 751, a second layer 752 and a third layer 753. The diffusion from the second layer 752 into each of the third layer 753, the first coating layer 71, and the second coating layer 72 is more extensive than that from the first layer 751. The configuration described above therefore enables the semiconductor device A40 to form a stronger bond between the supporting layer 112 and the conductive layer 12 and improves the heat dissipation of the semiconductor device A40. The semiconductor device A40 has a configuration in common with the semiconductor device A10, thereby achieving the same effect as the semiconductor device A10.

The present disclosure is not limited to the specific embodiments described above. Various design modifications may be made freely in the specific structure of each part according to the present disclosure.

The present disclosure includes embodiments described in the following clauses.

### Clause 1.

A semiconductor device comprising:
a supporting layer;
a conductive layer bonded to the supporting layer;
a semiconductor element located opposite the supporting layer with respect to the conductive layer and bonded to the conductive layer;
a first coating layer located between the supporting layer and the conductive layer and covering the supporting layer;
a second coating layer located between the first coating layer and the conductive layer and covering the conductive layer; and
a bonding layer bonding the first coating layer and the second coating layer,
wherein the bonding layer includes a base layer, a third coating layer located between the base layer and the first coating layer, and a fourth coating layer located between the base layer and the second coating layer,
a solid-state bonding layer is formed between the first coating layer and the third coating layer and between the second coating layer and the fourth coating layer,
the base layer has a lower Vickers hardness than each of the supporting layer and the conductive layer,
each of the third coating layer and the fourth coating layer includes a first layer covering the base layer, a second layer covering the first layer, and a third layer covering the second layer, and
diffusion from the second layer into each of the third layer, the first coating layer, and the second coating layer is more extensive than diffusion from the first layer into each of the third layer, the first coating layer, and the second coating layer.

### Clause 2.

The semiconductor device according to Clause 1, wherein the second layer contains a metal that is contained in each of the supporting layer and the conductive layer.

### Clause 3.

The semiconductor device according to Clause 2, wherein each of the supporting layer, the conductive layer, and the second layer contains copper.

### Clause 4.

The semiconductor device according to Clause 2 or 3, wherein each of the first coating layer, the second coating layer, and the third layer contains either silver or gold.

### Clause 5.

The semiconductor device according to any one of Clauses 2 to 4, wherein the base layer contains aluminum.

### Clause 6.

The semiconductor device according to any one of Clauses 2 to 5, wherein the first layer has a higher Vickers hardness than the second layer.

### Clause 7.

The semiconductor device according to Clause 6, wherein the first layer contains nickel.

### Clause 8.

The semiconductor device according to Clause 6 or 7, wherein the first coating layer includes a fourth layer covering the supporting layer, a fifth layer covering the fourth layer, and a sixth layer covering the fifth layer,
the fourth layer contains a same metal as that contained in the first layer,
the fifth layer contains a same metal as that contained in the second layer, and
diffusion from the fifth layer into the sixth layer is more extensive than diffusion from the fourth layer into the sixth layer.

### Clause 9.

The semiconductor device according to Clause 6, further comprising an insulating layer located opposite the conductive layer with respect to the supporting layer,
wherein the supporting layer is bonded to the insulating layer.

### Clause 10.

The semiconductor device according to Clause 9, wherein the semiconductor element includes a first electrode facing the conductive layer, and
the first electrode is conductively bonded to the conductive layer.

### Clause 11.

The semiconductor device according to Clause 10, wherein the conductive layer has a greater thickness than the supporting layer.

### Clause 12.

The semiconductor device according to Clause 11, wherein in plan view, the conductive layer is enclosed in a peripheral edge of the supporting layer.

### Clause 13.

The semiconductor device according to Clause 11, wherein the conductive layer includes a reverse surface covered with the second coating layer, and
in plan view, the reverse surface is enclosed in a peripheral edge of the supporting layer.

### Clause 14.

The semiconductor device according to Clause 13, wherein the conductive layer includes an obverse surface facing the first electrode, and
the obverse surface has a larger area than the reverse surface.

### Clause 15.

The semiconductor device according to any one of Clauses 9 to 14, further comprising a heat-dissipating layer located opposite the supporting layer with respect to the insulating layer,
wherein the heat-dissipating layer is bonded to the insulating layer.

### Clause 16.

The semiconductor device according to Clause 15, wherein the heat-dissipating layer has a greater thickness than the supporting layer.

### Clause 17.

The semiconductor device according to Clause 15 or 16, further comprising a sealing resin covering the supporting layer, the conductive layer, and the semiconductor element,
wherein the heat-dissipating layer is exposed to outside from the sealing resin.

REFERENCE NUMERALS

| | | |
|---|---|---|
| A10, A20, A30, A40: semiconductor device | | |
| 11: substrate | 111: insulating layer | |
| 111A: peripheral edge | 112: supporting layer | |
| 112A: peripheral edge | 113: heat-dissipating layer | |
| 12: conductive layer | 12A: first conductive layer | |
| 12B: second conductive layer | 121: obverse surface | |
| 122: reverse surface | 13: first input terminal | |
| 13A: covered portion | 13B: exposed portion | |
| 14: output terminal | 14A: covered portion | |
| 14B: exposed portion | 15: second input terminal | |
| 15A: covered portion | 15B: exposed portion | |
| 161: first signal terminal | 162: second signal terminal | |
| 171: third signal terminal | 172: fourth signal terminal | |
| 181: fifth signal terminal | 182: sixth signal terminal | |
| 19: seventh signal terminal | 21: semiconductor element | |
| 21A: first element | 21B: second element | |
| 211: first electrode | 212: second electrode | |
| 213: third electrode | 214: fourth electrode | |
| 22: thermistor | 29: conductive bonding layer | |
| 31: first conductive member | 311: body | |
| 312: first bonding portion | 313: first connecting portion | |
| 314: second bonding portion | 315: second connecting portion | |
| 32: second conductive member | 321: body | |
| 322: third bonding portion | 323: third connecting portion | |
| 324: fourth bonding portion | 325: fourth connecting portion | |
| 326: intermediate portion | 327: cross beam | |
| 33: first conductive bonding layer | | |
| 34: second conductive bonding layer | | |
| 35: third conductive bonding layer | | |
| 36: fourth conductive bonding layer | | |
| 41: first wire | 42: second wire | |
| 43: third wire | 44: fourth wire | |
| 50: sealing resin | 51: top surface | |
| 52: bottom surface | 53: first side surface | |
| 54: second side surface | 55: recessed portion | |
| 60: control wiring | 601: first wiring | |
| 602: second wiring | 61: insulating layer | |
| 62: wiring layer | 621: first wiring layer | |
| 622: second wiring layer | 623: third wiring layer | |
| 624: fourth wiring layer | 625: fifth wiring layer | |
| 63: intermediate layer | 64: sleeve | |
| 641: end surface | 68: first bonding layer | |
| 69: second bonding layer | 71: first coating layer | |
| 72: second coating layer | 73: bonding layer | |
| 731: base layer | 732: third coating layer | |
| 733: fourth coating layer | 74: solid-state bonding layer | |
| 74A: first bonding layer | 74B: second bonding layer | |
| 751: first layer | 752: second layer | |
| 753: third layer | 754: fourth layer | |
| 755: fifth layer | 756: sixth layer | |
| 757: seventh layer | 758: eighth layer | |
| 759: ninth layer | z: first direction | x: second direction |
| y: third direction | | |

1. A semiconductor device comprising:
a supporting layer;
a conductive layer bonded to the supporting layer;
a semiconductor element located opposite the supporting layer with respect to the conductive layer and bonded to the conductive layer;
a first coating layer located between the supporting layer and the conductive layer and covering the supporting layer;
a second coating layer located between the first coating layer and the conductive layer and covering the conductive layer; and
a bonding layer bonding the first coating layer and the second coating layer,
wherein the bonding layer includes a base layer, a third coating layer located between the base layer and the first coating layer, and a fourth coating layer located between the base layer and the second coating layer,
a solid-state bonding layer is formed between the first coating layer and the third coating layer and between the second coating layer and the fourth coating layer,
the base layer has a lower Vickers hardness than each of the supporting layer and the conductive layer,
each of the third coating layer and the fourth coating layer includes a first layer covering the base layer, a second layer covering the first layer, and a third layer covering the second layer, and
diffusion from the second layer into each of the third layer, the first coating layer, and the second coating layer is more extensive than diffusion from the first layer into each of the third layer, the first coating layer, and the second coating layer.

2. The semiconductor device according to claim 1, wherein the second layer contains a metal that is contained in each of the supporting layer and the conductive layer.

3. The semiconductor device according to claim 2, wherein each of the supporting layer, the conductive layer, and the second layer contains copper.

4. The semiconductor device according to claim 2, wherein each of the first coating layer, the second coating layer, and the third layer contains either silver or gold.

5. The semiconductor device according to claim 2, wherein the base layer contains aluminum.

6. The semiconductor device according to claim 2, wherein the first layer has a higher Vickers hardness than the second layer.

7. The semiconductor device according to claim 6, wherein the first layer contains nickel.

8. The semiconductor device according to claim 6, wherein the first coating layer includes a fourth layer covering the supporting layer, a fifth layer covering the fourth layer, and a sixth layer covering the fifth layer,
the fourth layer contains a same metal as that contained in the first layer,
the fifth layer contains a same metal as that contained in the second layer, and
diffusion from the fifth layer into the sixth layer is more extensive than diffusion from the fourth layer into the sixth layer.

9. The semiconductor device according to claim 6, further comprising an insulating layer located opposite the conductive layer with respect to the supporting layer,
wherein the supporting layer is bonded to the insulating layer.

10. The semiconductor device according to claim 9, wherein the semiconductor element includes a first electrode facing the conductive layer, and
the first electrode is conductively bonded to the conductive layer.

11. The semiconductor device according to claim 10, wherein the conductive layer has a greater thickness than the supporting layer.

12. The semiconductor device according to claim 11, wherein in plan view, the conductive layer is enclosed in a peripheral edge of the supporting layer.

13. The semiconductor device according to claim 11, wherein the conductive layer includes a reverse surface covered with the second coating layer, and
in plan view, the reverse surface is enclosed in a peripheral edge of the supporting layer.

14. The semiconductor device according to claim 13, wherein the conductive layer includes an obverse surface facing the first electrode, and
the obverse surface has a larger area than the reverse surface.

15. The semiconductor device according to claim 9, further comprising a heat-dissipating layer located opposite the supporting layer with respect to the insulating layer,
wherein the heat-dissipating layer is bonded to the insulating layer.

16. The semiconductor device according to claim 15, wherein the heat-dissipating layer has a greater thickness than the supporting layer.

17. The semiconductor device according to claim 15, further comprising a sealing resin covering the supporting layer, the conductive layer, and the semiconductor element,
wherein the heat-dissipating layer is exposed to outside from the sealing resin.
